(19) United States
(12) Patent Application Publication
(10) Pub. No.: US 2004/0238962 A1
(43) Pub. Date: Dec. 2, 2004

(54) Semiconductor device including metal interconnection and metal resistor and method of manufacturing the same

(76) Inventors: Mu-Kyeng Jung, Suwon-City (KR); Kyung-Tae Lee, Gwacheon-City (KR); Jeong-Hoon Ahn, Seoul (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 10/824,399

(22) Filed: Apr. 15, 2004

(30) Foreign Application Priority Data
May 14, 2003 (KR) 2003-30510

(51) Int. Cl. H01L 23/48

(52) U.S. Cl. 257/758

(57) ABSTRACT

A semiconductor device includes a metal interconnection and a metal resistor. The device is made by forming a lower interconnection of copper within an insulating layer, forming a capping layer on the insulating layer to cover and protect the lower interconnection, forming a window in the capping layer to selectively expose a top surface of the lower interconnection, and forming a metal resistor on the capping layer and which contacts the top surface of the lower interconnection through the window. Then an electrical contact is formed in the insulating layer. Alternatively, the metal resistor may be formed on the insulating layer after the electrical contact is formed.

### BACKGROUND OF THE INVENTION

1. Field of the Invention

The present invention relates to a method of manufacturing a semiconductor device. More particularly, the present invention relates to a semiconductor device including a metal resistor electrically connected to a metal interconnection and to a method of manufacturing the same.

2. Description of the Related Art

In recent years, the design of system-on-chip (SOC) semiconductor devices has progressed considerably along with significant developments in wire and wireless communication systems in which the SOC semiconductor devices are used for processing analog or mixed signals. As such, today's SOC semiconductor devices require high-quality resistors. In particular, the semiconductor devices require excellent matching characteristics between resistors.

FIG. 1 is a circuit diagram of a conventional semiconductor device, illustrating the characteristics of a resistor.

Referring to FIG. 1, excellent matching characteristics between resistors 11 and 13 are needed to provide the conventional semiconductor device with enhanced operating characteristics. More specifically, resistor patterns must be manufactured uniformly if the resulting resistors 11 and 13 are to have matching characteristics. Above all, the resistance must not be affected by other semiconductor device manufacturing processes performed after the resistors are formed.

Conventionally, a resistor of a semiconductor device is formed of polysilicon or using an active region. However, controlling the resistance offered by this kind of resistor is difficult because it is difficult to form a resistor pattern with a high degree of precision. Also, characteristics of the resistor pattern can be easily affected by other manufacturing processes after it is formed. Thus, various forms of metal resistors have been proposed to overcome the restrictions posed by resistors formed of polysilicon or using an active region. For example, Japanese Patent Laid-open Publication No. 2002-231891 entitled “Method of Manufacturing Semiconductor Device,” dated Aug. 16, 2002, discloses a method of forming a metal resistor connected to an aluminum alloy layer.

However, forming metal resistors remains problematic in the manufacturing of high-quality semiconductor devices. For example, a typical high-quality semiconductor device requires an electrical connection between multiple layers. The electrical connection is provided by a contact formed in a contact hole extending between the layers. However, it is difficult to obtain a reliable connection between such a contact and metal resistors formed on the layers. For example, the contact hole is formed by an etching process. A metal resistor may be greatly damaged or lost entirely due to over-etching when the contact hole is being formed.

FIGS. 2 through 4 illustrate the problems that may occur when a metal resistor is connected to a contact.

Referring to FIGS. 2 through 4, to form a typical multi-layered semiconductor device, a first interconnection 31 is formed through a first insulating layer 21, a protection layer 41 is formed on the first insulating layer 21, and a metal resistor 50 is formed on the protection layer 41. Next, an etch stop layer 45 is formed to cover the metal resistor 50 and to extend over the first interconnection 31. A second insulating layer 25 is formed on the etch stop layer 45. Contact holes 27 and 29 are then formed by etching the second insulating layer 25. The contact holes 27 and 29 penetrate the second insulating layer 25. The first contact hole 27 is aligned with and disposed over the first interconnection 31, and the second contact hole 29 will be used to connect the metal resistor 50 and an interconnection.

As this etch process is performed, a portion of the etch stop layer 45, that is disposed on the metal resistor 50, is firstly exposed, as shown in FIG. 2. At this time, the first contact hole 27 and the second contact hole 29 are etched to identical depths. However, the top surface of the first interconnection 31 must be exposed by the first contact hole 27. Accordingly, the etch process is further performed, as shown in FIG. 3, until the first contact hole 27 also exposes the etch stop layer 45. Then, the etch process is performed even further to selectively remove the etch stop layer 45. As a result, the second contact hole 29 starts to expose the metal resistor 50.

Once the etch stop layer 45 is removed, the first contact hole 27 exposes the protection layer 41 but not the first interconnection 31. Accordingly, the etch process is further performed until the first interconnection 31 is finally exposed. This prolonged etch process seriously erodes the exposed metal resistor. As a result, the portion 53 of the metal resistor 50 exposed by the second contact hole 29 is thinned out or even completely removed.

A first contact 37 and a second contact 39 are formed to fill the contact holes 27 and 29, respectively. A third insulating layer 28 is formed on the second insulator layer 25. A second interconnection 35 is then formed through the third insulating layer 28 as connected to the contacts 37 and 39, as shown in FIG. 4. The second interconnection 35 is thus electrically connected to the metal resistor 50 by the second contact 39 via the thin portion 53 of the metal resistor 50. Although the second contact 39 contacts a major surface of the thin portion 53 of the metal resistor 50, a large amount of current flows from the second contact 39 through lateral portions 55 of the metal resistor 50.

In other words, the effective area of contact between the second contact 39 and the metal resistor 50, through which a large current flows, is limited, and current flow is concentrated on the lateral portions 55 of the metal resistor 50. The concentration of current at the lateral portions 55 may permit local heating at the lateral portions 55, thereby causing a contact failure between the lateral portions 55 and the second contact 39. In this case, the electrical connection between the metal resistor 50 and the second contact 39 becomes unreliable, and a short may even occur therebetween. Thus, erosion of the metal resistor 50 must be prevented during the formation of the contact holes 27 and 29. However, this is difficult to do in practice.

Furthermore, the sheet resistance of the metal resistor 50 used in a semiconductor device should be several hundred ohms/cm² or higher. To this end, the metal layer from which the metal resistor 50 is formed should have a thickness of no more than 1000 Å. However, forming the metal resistor 50 from a thin metal layer makes it even more likely that a contact failure will develop. That is, an etch margin of about 500 Å is needed to complete the forming of the contact holes 27 and 29. However, such an etch margin makes it very likely that the exposed portion of the metal resistor 50 may be seriously eroded. On the other hand, the resistance of the metal resistor 50 cannot be sufficiently high if the metal resistor 50 is not thin.

Thus, the use of metal resistors in semiconductor devices is limited by problems associated with the processes typically used to form the devices.

### SUMMARY OF THE INVENTION

One object of the present invention is to provide a semiconductor device including a metal resistor that is reliably electrically connected to a metal interconnection.

Another object of the present invention is to provide a method of manufacturing a semiconductor device having a metal resistor, and which avoids eroding or removing a portion of the metal resistor during the forming of a contact for connecting the metal resistor to a metal interconnection.

According to one aspect of the present invention, a semiconductor device comprises an interconnection of copper surrounded by an insulating layer; a capping layer that covers and protects the interconnection, and a metal resistor that contacts a top surface of the interconnection through a window in the capping layer.

According to another aspect of the present invention, the semiconductor device comprises an interconnection, an insulating layer covering the interconnection, an electrical contact such as a contact plug that penetrates the insulating layer and is electrically connected to the interconnection, and a metal resistor that extends onto the insulating layer and contacts the electrical contact.

The semiconductor device may also comprise an MIM capacitor disposed on the insulating layer. Preferably, the metal resistor is of the same material as a lower electrode or an upper electrode of the MIM capacitor.

According to another aspect of the present invention, there is provided a method of manufacturing a semiconductor device, comprising forming an insulating layer, forming a lower interconnection of copper surrounded by the insulating layer, forming a capping layer on the insulating layer to cover and protect the lower interconnection, forming a window in the capping layer to selectively expose a top surface of the lower interconnection, and forming a metal resistor on the capping layer to contact the top surface of the lower interconnection through the window.

According to yet another aspect of the present invention of the present invention, there is provided a method of manufacturing a semiconductor device, comprising forming an insulating layer; forming a first lower interconnection and a second lower interconnection of copper surrounded by the insulating layer, forming a capping layer on the insulating layer to cover and protect the first lower interconnection and the second lower interconnection, forming a window in the capping layer to selectively expose a top surface of the first lower interconnection, forming a metal resistor on the capping layer to contact the top surface of the first lower interconnection through the window, forming a second insulating layer to cover the metal resistor, forming an electrical contact that penetrates the second insulating layer so as to contact the second lower interconnection, and forming an upper interconnection electrically connected to the contact.

According to still another aspect of the present invention, there is provided a method of manufacturing a semiconductor device, comprising forming an insulating layer, forming a first lower interconnection and a second lower interconnection of copper surrounded by the insulating layer, forming a capping layer on the insulating layer to cover and protect the first lower interconnection and the second lower interconnection, forming a window in the capping layer to selectively expose a top surface of the first lower interconnection, forming on the capping layer a metal layer that contacts the top surface of the first lower interconnection through the window, patterning the metal layer to form a metal electrode of a MIM capacitor and a metal resistor contacting the first lower interconnection through the window, forming a second insulating layer to cover the metal resistor and the capacitor, forming an electrical contact that penetrates the second insulating layer to contact the second lower interconnection, and forming an upper interconnection electrically connected to the contact.

The forming of the lower interconnection may comprise forming a trench in the insulating layer, forming a copper layer on the insulating layer to fill the trench, and planarizing the copper layer until the top surface of the insulating layer is exposed. As a result, the lower interconnection assumes the shape of the trench.

Also, the capping layer may be formed of silicon nitride or silicon carbide. The metal resistor may be formed of titanium (Ti), titanium nitride (TiN), tantalum (Ta), tantalum nitride (TaN), or tantalum silicon nitride (TaSiN). The electrical contact and the upper interconnection may be formed from a copper layer using a damascene process.

The metal electrode that is formed at the same time as the metal resistor, i.e., from the same metal layer, may be the upper electrode of the capacitor. In this case, the capping layer may extend beneath the upper electrode to function as a dielectric layer of the capacitor. The method of the present invention may further comprise forming a lower electrode under the capping layer as opposed to the upper electrode. For example, the lower electrode may be formed in the insulating layer at the same time as the first lower interconnection and the second lower interconnection.

Alternatively, the method of the present invention may comprise forming the lower electrode on the capping layer. In this case, a discrete dielectric layer is formed on the lower electrode.

Still, though, the metal electrode that is formed at the same time as the metal resistor, i.e., from the same metal layer, may be the lower electrode of the capacitor. In this case, a dielectric layer is formed to cover the lower electrode, and an upper electrode is formed on the dielectric layer as opposed to the lower electrode.

According to still another aspect of the present invention, there is provided a method of manufacturing a semiconductor device, comprising forming an insulating layer, forming a first lower interconnection, a second lower interconnection, and a third lower interconnection of copper surrounded by the insulating layer, forming a capping layer on the insulating layer to cover and protect the interconnections, forming a first window in the capping layer to selectively expose a top surface of the first lower interconnection, forming a lower electrode layer on the capping layer to contact the top surface of the first lower interconnection through the first window, patterning the lower electrode layer to form a lower electrode of an MIM capacitor and a first metal resistor contacting the first lower interconnection through the first window, forming a dielectric layer to cover the first metal resistor and the first lower electrode, forming a second window in the dielectric layer and the capping layer to selectively expose a top surface of the second lower interconnection, forming an upper electrode layer on the dielectric layer to contact the top surface of the second lower interconnection through the second window, patterning the upper electrode to form an upper electrode facing the lower electrode and a second metal resistor contacting the second lower interconnection through the second window, forming a second insulating layer to cover the second metal resistor and the upper electrode, forming an electrical contact that penetrates the second insulating layer and contacts the top surface of the third interconnection, and forming an upper interconnection electrically connected to the contact.

According to still yet another aspect of the present invention, there is provided a method of manufacturing a semiconductor device, comprising forming an interconnection, forming an insulating layer to cover the interconnection, forming an electrical contact penetrating the insulating layer and electrically connected to the interconnection, and forming a metal resistor on the insulating layer in contact with the electrical contact.

The contact may be formed of a body of copper. In this case, the method may further comprise forming a capping layer under the metal resistor to cover and protect a surface of the copper contact body, and forming a window in the capping layer to expose the surface of the copper contact body.

### BRIEF DESCRIPTION OF THE DRAWINGS

The above and other objects, features and advantages of the present invention will become more apparent from the following detailed description of the preferred embodiments thereof made with reference to the attached drawings, in which:

FIG. 1 is a circuit diagram of a conventional semiconductor device having the characteristics of a resistor;

FIGS. 2 through 4 are cross-sectional views of a semiconductor device structure, illustrating a method of making a conventional multi-layered semiconductor device comprising a metal resistor;

FIGS. 5 through 10 are cross-sectional views of a semiconductor device structure illustrating a first embodiment of a method of manufacturing a semiconductor device, in which a metal resistor is electrically connected to a metal interconnection, according to the present invention;

FIGS. 11A and 11B are plan views of a metal resistor of a semiconductor device according to the present invention;

FIGS. 12 through 14 are cross-sectional views of a semiconductor device structure illustrating a second embodiment of a method of manufacturing a semiconductor device, in which a metal resistor is electrically connected to a metal interconnection, according to the present invention;

FIGS. 15 through 18 are cross-sectional views of a semiconductor device structure illustrating a third embodiment of a method of manufacturing a semiconductor device, in which a metal resistor is electrically connected to a metal interconnection, according to the present invention;

FIGS. 19 through 22 are cross-sectional views of a semiconductor device structure illustrating a fourth embodiment of a method of manufacturing a semiconductor device, in which a metal resistor is electrically connected to a metal interconnection, according to the present invention;

FIG. 23 is a cross-sectional view of a semiconductor device structure illustrating a fifth embodiment of a method of manufacturing a semiconductor device; in which a metal resistor is electrically connected to a metal interconnection, according to the present invention; and

FIG. 24 is a cross-sectional view of a semiconductor device structure illustrating a sixth embodiment of a method of manufacturing a semiconductor device, in which a metal resistor is electrically connected to a metal interconnection, according to the present invention.

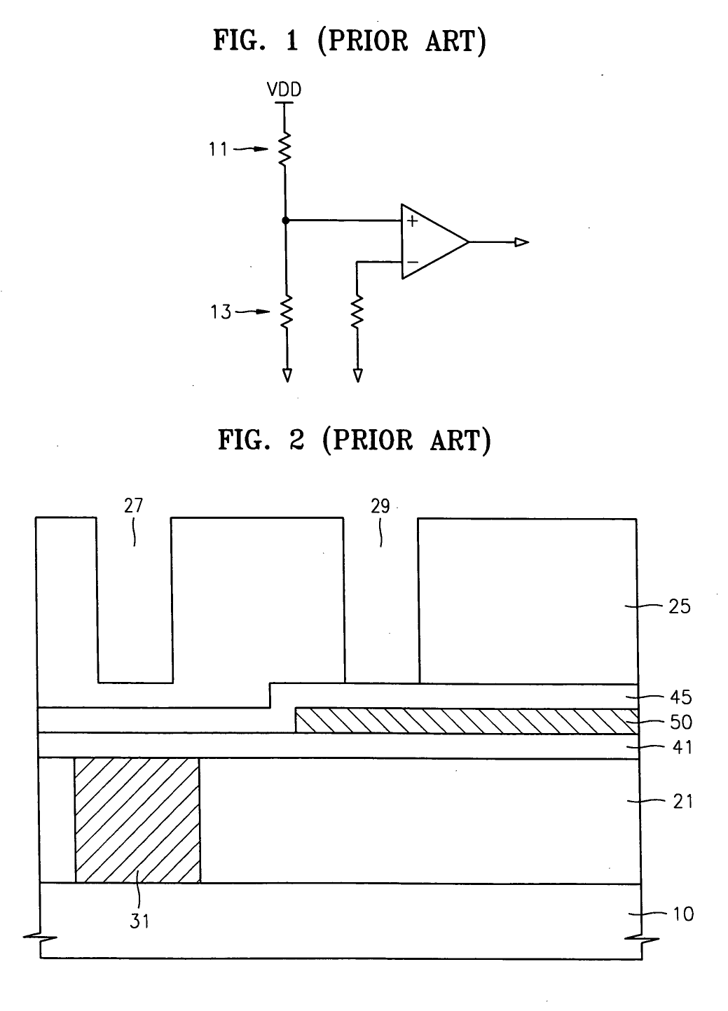

### DETAILED DESCRIPTION OF THE PREFERRED EMBODIMENTS

The present invention will now be described more fully with reference to the accompanying drawings. In the drawings, the thicknesses of layers may be exaggerated for clarity, and the same reference numerals are used to denote the same elements throughout the drawings.

### Embodiment 1

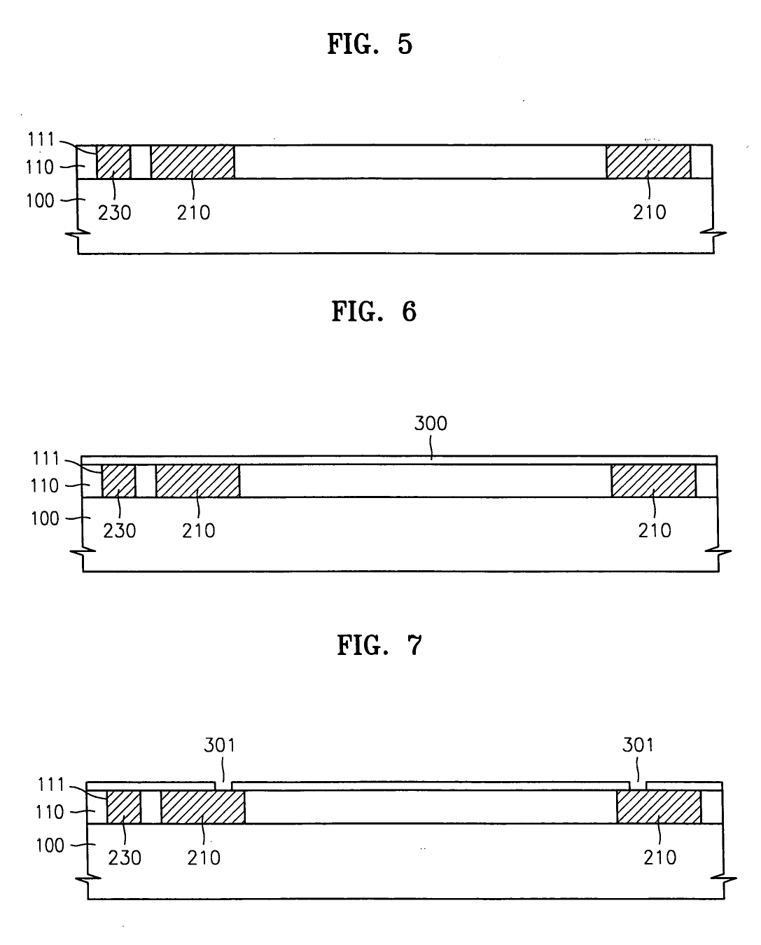

Referring to FIG. 5, lower interconnections 210 and 230 are formed to extend through a first insulating layer 110. The first insulating layer is formed on a semiconductor substrate 100, and devices for enabling the operations of the semiconductor device (e.g., transistors) are disposed between the semiconductor substrate and the first insulating layer 110. The semiconductor device may be an SOC semiconductor device that processes analog or mixed signals. More generally, the substrate 100 preferably has an upper portion comprising an upper dielectric layer. The upper portion may comprise an inter metal dielectric (IMD) or interlevel dielectric (ILD) layer embedded with conductors or lines. The semiconductor substrate 100 thus may understood to include a semiconductor wafer, active and passive devices formed within the wafer, and insulating and conductive layers formed on the wafer. In any case, the term “upper portion” of the substrate may refer to the uppermost layers on a semiconductor wafer, such as an insulating layer and/or a layer of conducive lines.

Also, for purposes of explanation, the first lower interconnections 210 refer to those lower interconnections that will be connected to a metal resistor, whereas the second lower interconnections 230 refer to those lower interconnections that will be connected to upper interconnections through a via contact. The lower interconnections 210 and 230 may be copper interconnections, which are preferably formed using a damascene process. For instance, after the first insulating layer 110 is formed on the substrate, first trenches 111 are formed in the first insulating layer 110, and a copper layer is formed by electroplating the first insulating layer 110 to fill the first trenches 111. In this case, a metal barrier layer and a seed layer may be disposed under the copper layer. Subsequently, the copper layer is planarized using chemical mechanical polishing (CMP), thereby forming the lower interconnections 210 and 230.

Although the lower interconnections 210 and 230 formed of a copper layer have a high conductivity of about 1.7 μΩ·μm and, therefore, possess excellent electric properties, the copper layer itself may be easily damaged by the atmosphere. In particular, the lower interconnections 210 and 230 may be oxidized or contaminated when they are exposed to the atmosphere.

A thin capping layer 300 is thus formed on the lower interconnections 210 and 230, as shown in FIG. 6, to prevent the lower interconnections 210 and 230 from being oxidized or contaminated. The capping layer 300 may be formed of insulating materials, such as silicon nitride SiN and silicon carbide SiC. The capping layer 300 is formed to a thickness of only several hundred Å, for example, because it only needs to prevent the top surfaces of the lower interconnections 210 and 230 from being exposed to the atmosphere.

Referring to FIG. 7, the capping layer 300 is selectively etched, thereby forming windows 301 exposing the top surfaces of the first lower interconnections 210. These windows 301 will be used to connect a metal resistor to the first lower interconnections 210. Accordingly, the windows 301 are formed only on the first lower interconnections 210.

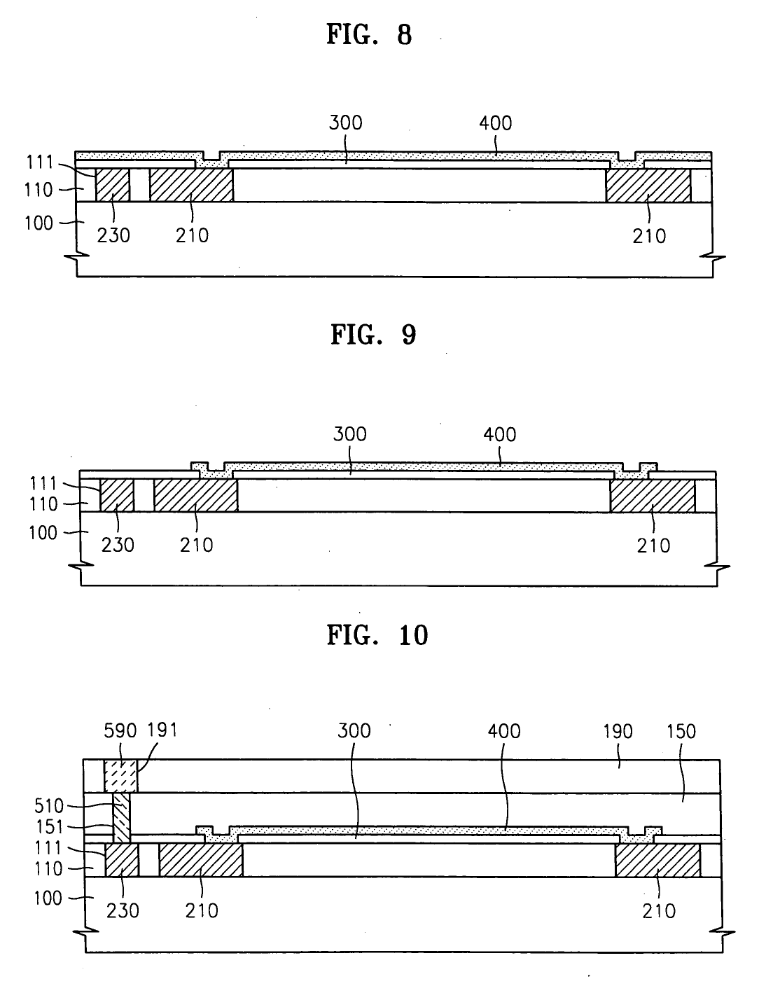

Referring to FIG. 8, a metal resistor layer is formed on the capping layer 300 to a thickness of about 30 Å to 1000 Å to contact the top surfaces of the first lower interconnections 210. The metal resistor layer may be formed of various materials, such as titanium, titanium nitride, tantalum, tantalum nitride, and tantalum silicon nitride. The metal resistor layer is made as thin as possible so that the metal resistor formed therefrom offers a high resistance. Preferably, the metal resistor layer is formed to a thickness of about 500 Å or less, for example, 30 Å to 300 Å. A metal resistor 400 having a thickness of about 500 Å or less can have a higher resistance than conventional resistors formed of polysilicon or using an active region.

Referring to FIG. 9, the metal resistor layer is patterned using photolithography and etch processes so as to have a very precise profile. The photolithography and etch processes may or may not use a hard mask. Using the photolithography and etch processes ensures that the pattern of the metal resistor 400 is precisely formed. Also, the metal resistor 400 is not affected by subsequent processes. This is because the subsequent processes, i.e., those following the formation of the metal interconnections, generally do not include high-temperature thermal processes which might otherwise affect the line width of the pattern or the characteristics of the metal resistor. Thus, the metal resistor 400 can have a resistance accurate to that to which the resistor was designed. Therefore, resistors having matching characteristics can be readily produced, and the resulting semiconductor devices can operate with a high degree of reliability.

Also, the pattern of the metal resistor 400 may be used to achieve the desired resistance. For example, the patterning of the metal resistor layer may yield a metal resistor 451 having a linear shape, as shown in FIG. 11A, or a metal resistor 453 having a series of bends or undulations between the first lower interconnections 210, as shown in FIG. 11B. The metal resistor 453 having the series of bends, as shown in FIG. 11B, offers a higher resistance than that of the corresponding metal resistor 451 having the linear shape.

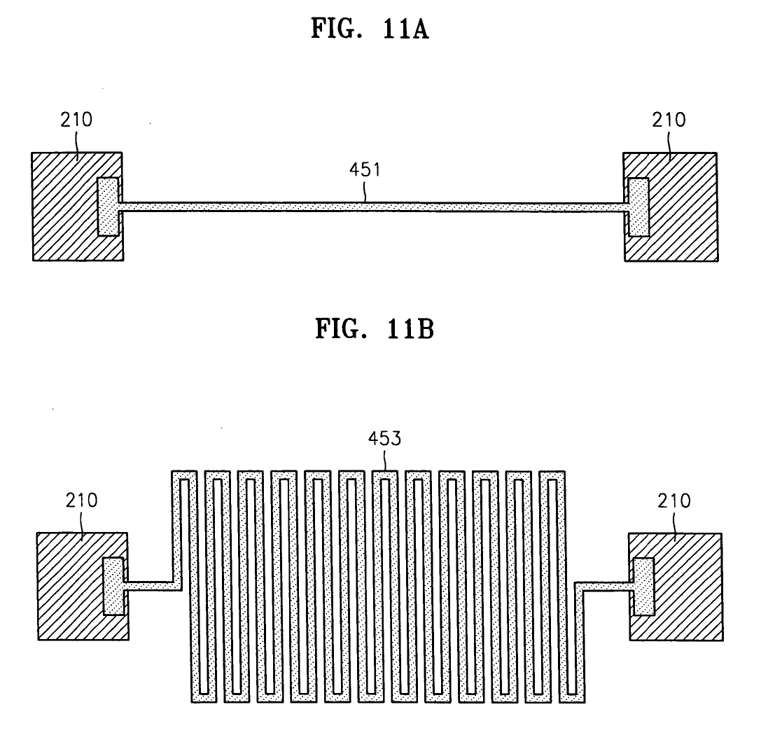

Referring now to FIG. 10, a second insulating layer 150 is formed to cover the metal resistor 400. Subsequently, a via contact hole 151 is formed through the second insulating layer 150. The contact hole 151 is formed in alignment with the second lower interconnection 230. Accordingly, there is no erosion or removal of the metal resistor 400 during the etch process for forming the contact hole 151.

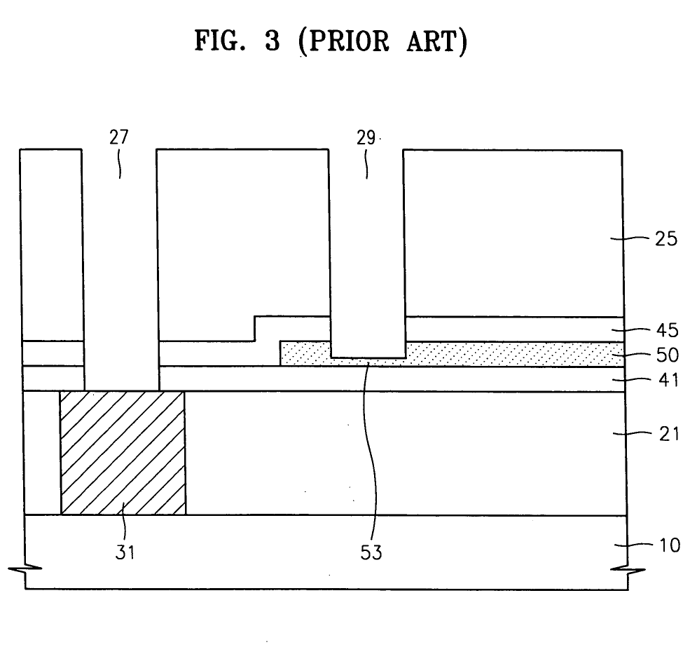

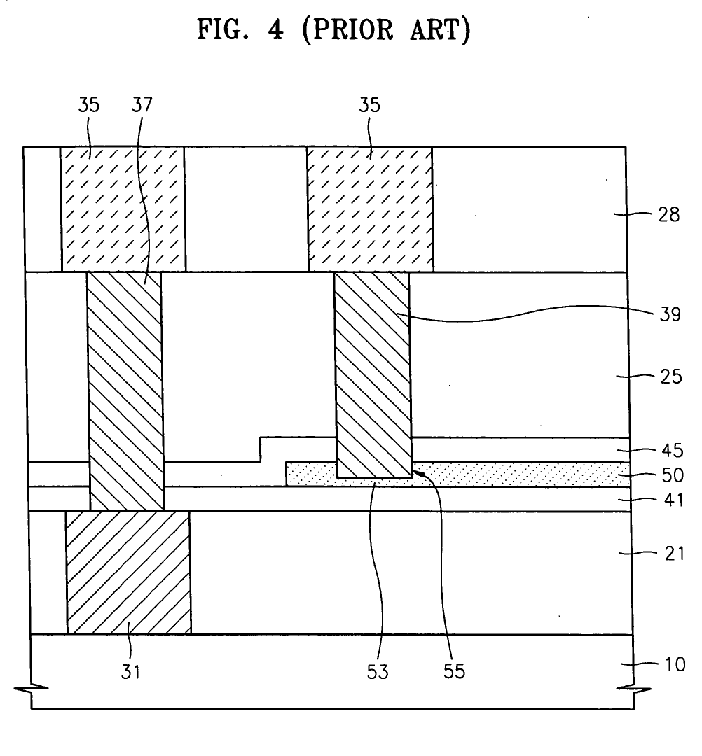

Meanwhile, the capping layer 300 may be used as an etch stop layer during the etch process for forming the contact hole 151. As described above, the capping layer 300 is formed of silicon nitride or silicon carbide that has a high etch selectivity with respect to the silicon oxide that is used to form the second insulating layer 150. Accordingly, the present invention obviates the need for the etch stop layer described with reference to the prior art of FIGS. 2 through 4.

After the contact hole 151 is formed, a contact (plug) 510 is formed to fill the contact hole 151. The contact 510 may be formed of metal, such as copper or tungsten, and preferably, copper.

Next, a third insulating layer 190 is formed to cover the contact 510, and then a second trench 191 is formed in the third insulating layer 190 using a damascene process. Subsequently, an upper interconnection 590 is formed to fill the second trench 191, thereby completing the multi-layered semiconductor device structure. In this case, the upper interconnection 590 may be formed of metal, preferably, copper, like the lower interconnections 210 and 230.

### Embodiment 2

In a second embodiment, a metal resistor is formed while an upper electrode of an MIM capacitor is being formed, i.e., without the need of additional deposition and patterning processes.

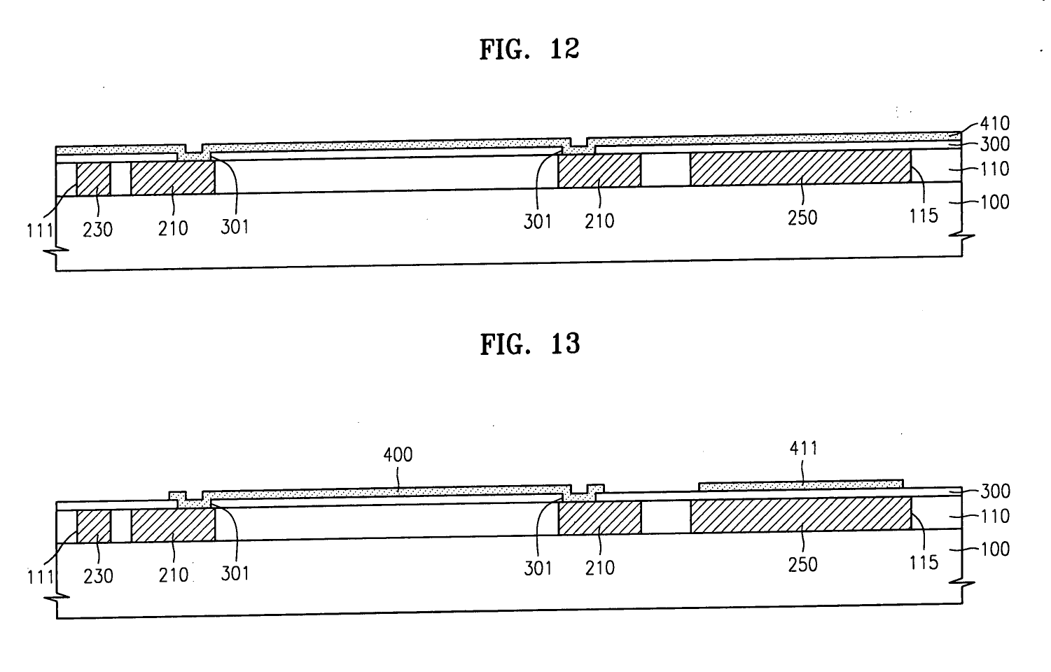

Referring to FIG. 12, and as described above with reference to FIGS. 5 through 7, lower interconnections 210 and 230 are formed using a damascene process in a first insulating layer 110. Also, a lower electrode 250 is formed at a position where the capacitor will be formed, at the same time the lower interconnections 210 and 230 are formed. That is, a third trench 115 is formed during the formation of first trenches 111, a copper layer is formed to fill the first and third trenches 111 and 115, and then the copper layer is planarized.

Subsequently, as described above with reference to FIG. 6, a capping layer 300 is formed on the first insulating layer 110, and windows 301 are formed in the capping layer 300. Then, an upper electrode layer 410 is formed on the capping layer 300 to contact the first lower interconnections 210 through the windows 301. The upper electrode layer 410 may be formed of various electrode materials. For example, like the metal resistor layer in the first embodiment, the upper electrode layer 410 may be formed of titanium, titanium nitride, tantalum, tantalum nitride, or tantalum silicon nitride.

Referring to FIG. 13, the upper electrode layer 410 is patterned to form a metal resistor 400 and an upper electrode 411. Thus, a portion of the capping layer 300, disposed between the upper electrode 411 and the lower electrode 250, is used as a dielectric layer of the capacitor.

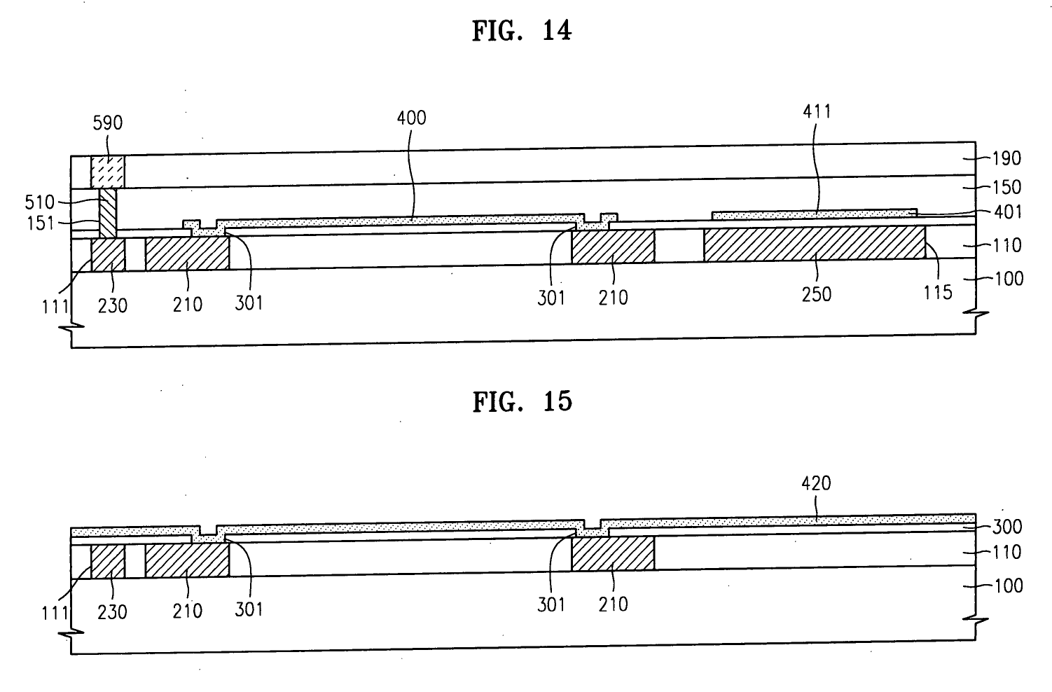

Referring to FIG. 14, a second insulating layer 150 is formed to cover the metal resistor 400 and the upper electrode 411, and then a contact 510 and an upper interconnection 590 are formed as described with reference to FIG. 10.

### Embodiment 3

In a third embodiment, a metal resistor is formed during the formation of a lower electrode of an MIM capacitor.

Referring to FIG. 15, as described with reference to FIGS. 5 through 7, lower interconnections 210 and 230 are formed in a first insulating layer 110 using a damascene process. Then, a capping layer 300 is formed as in the first embodiment, and a lower electrode layer 420 is formed on the capping layer 300 to contact the first lower interconnections 210 through windows 301. The lower electrode layer 420 may be formed of the same material as the metal resistor layer of the first embodiment.

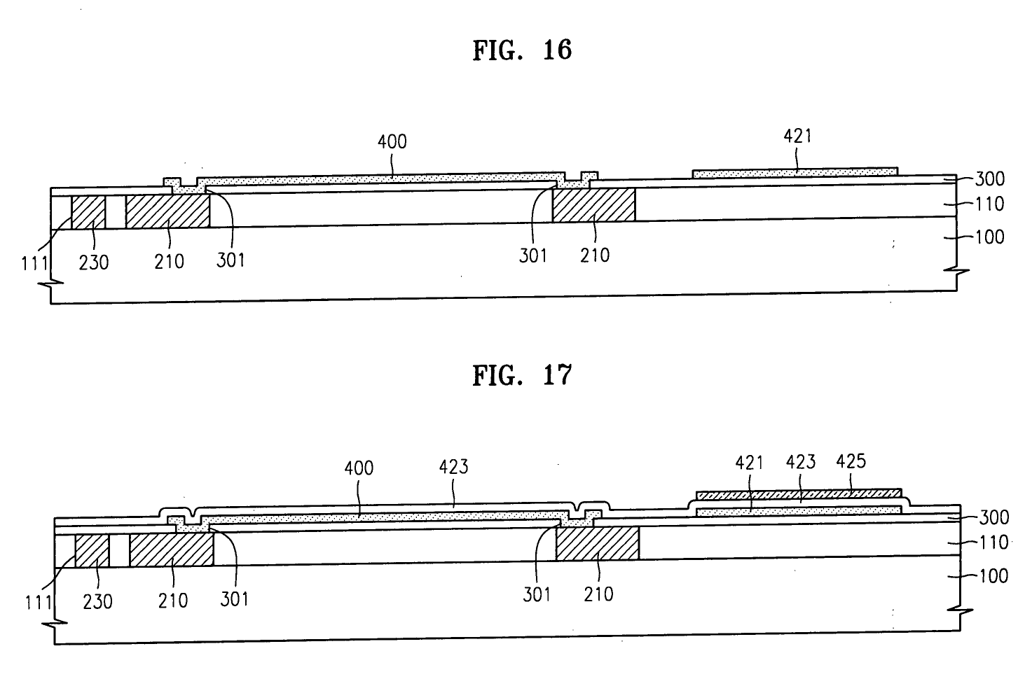

Referring to FIG. 16, the lower electrode layer 420 is patterned so as to form a metal resistor 400 and a lower electrode 421. The lower electrode 421 is formed at a position where a capacitor will be formed.

Referring to FIG. 17, a dielectric layer 423 is formed over the lower electrode 421. Next, an upper electrode layer is formed by depositing an electrode material on the dielectric layer 423, and then the upper electrode layer is patterned so as to form an upper electrode 425. Thus, an MIM capacitor is completed.

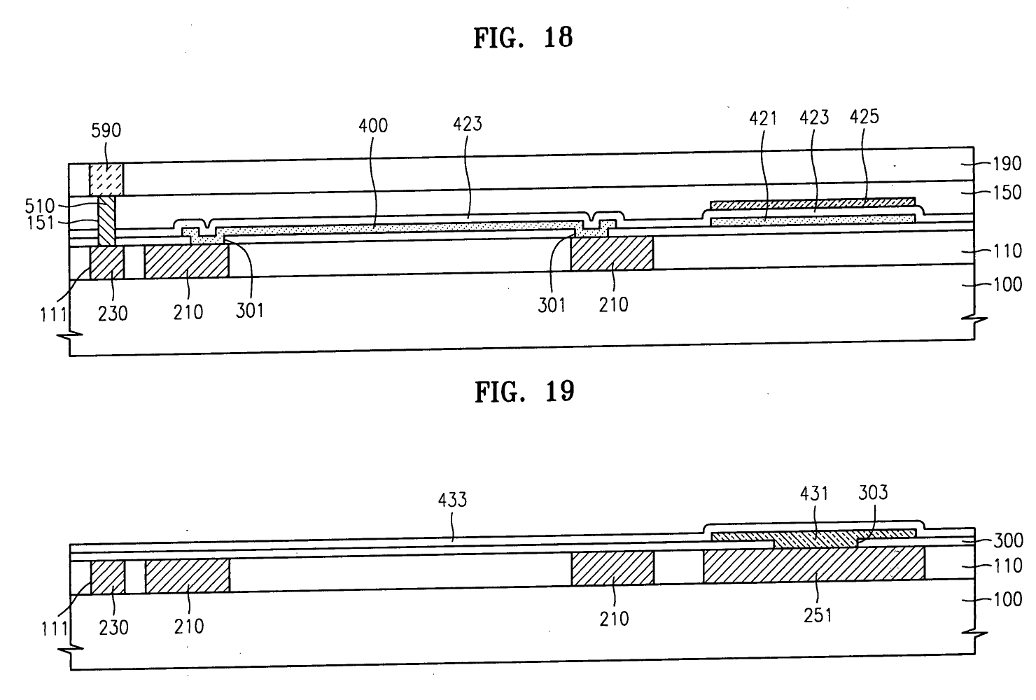

Referring to FIG. 18, a second insulating layer 150 is formed over the upper electrode 425. Subsequently, a contact 510 electrically connected to the second lower interconnection 230 and an upper interconnection 590 are formed, as described with reference to FIG. 10.

### Embodiment 4

Referring to FIG. 19, and as described above with reference to FIGS. 5 through 7, lower interconnections 210, 230 are formed in a first insulating layer 110 using a damascene process. Also, a third lower interconnection 251 is formed at a position where a capacitor will be formed, at the same time as the first and second lower interconnections 210 and 230. Next, a capping layer 300 is formed on the first insulating layer 1001, as described with reference to FIG. 6.

Subsequently, a first window 303 is formed in the capping layer 300 to expose a top surface of the third lower interconnection 251. Next, a lower electrode 431 is formed of any of various metal electrode materials in contact with the third lower interconnection 251 through the first window 303. Then, a dielectric layer 433 is formed over the lower electrode 431.

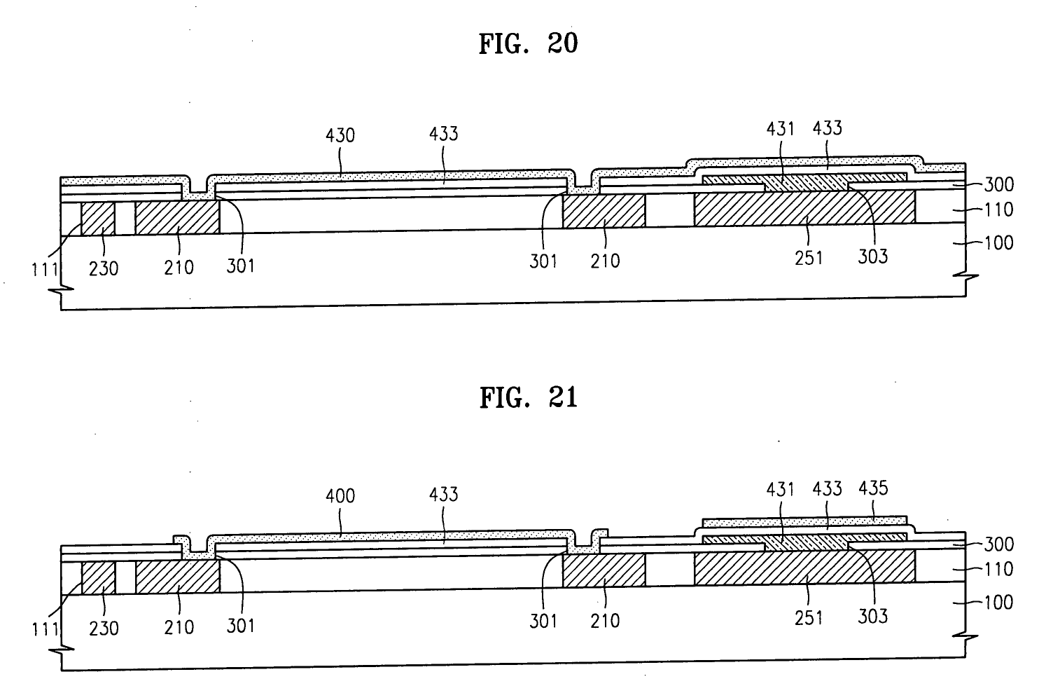

Referring to FIG. 20, the dielectric layer 433 and the capping layer 300 disposed thereunder are sequentially and selectively etched, thereby forming second windows 301 that expose the top surfaces of the first lower interconnections 210. Next, an upper electrode layer 430 is formed on the dielectric layer 431 in contact with the exposed first lower interconnections 210. Like the metal resistor layer of the first embodiment, the upper electrode layer 430 may be formed of titanium, titanium nitride, tantalum, tantalum nitride, and tantalum silicon nitride.

Referring to FIG. 21, the upper electrode layer 430 is patterned so as to form a metal resistor 400 and an upper electrode 435. Thus, an MIM capacitor, which includes the upper electrode 435, the lower electrode 431, and the dielectric layer 433 disposed therebetween, is completed. Also, in this embodiment, the metal resistor 400 is formed on the same level as the upper electrode 435.

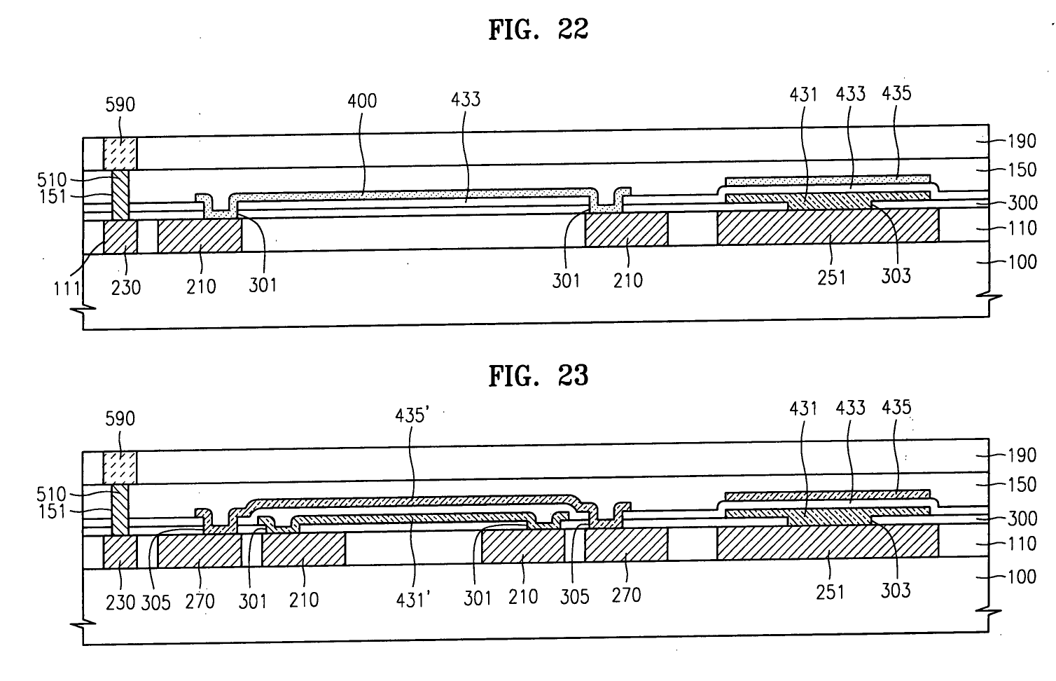

Referring to FIG. 22, a second insulating layer 150 is formed over the metal resistor 400 and the upper electrode 435, and then a contact 510 and an upper interconnection 590 are formed as described with reference to FIG. 10.

### Embodiment 5

In a fifth embodiment, metal resistors are formed during the formation of a lower electrode and an upper electrode of an MIM capacitor.

Referring to FIG. 23, as described with reference to FIGS. 5 through 7, lower interconnections 210, 230 are formed in a first insulating layer using a damascene process. Also, a third lower interconnection 251 is formed at a position where a capacitor will be formed, at the same time as the first lower interconnection 210 and the second lower interconnection 230. Also, a fourth lower interconnection 270 is formed at the same time as the first and second lower interconnections 210 and 230. Then, a capping layer 300 is formed on the first insulating layer 100, as described with reference to FIG. 6.

Subsequently, a first opening or window 303 is formed in the capping layer 300 to expose a top surface of the third lower interconnection 251. Second windows 301 are formed at the same time as the first window 303 to expose the top surface of the first lower interconnections 210. A lower electrode layer is formed, as described with reference to FIG. 17, to contact the third lower interconnection 251 through the first window 303 and to contact the first lower interconnection 210 through the second window 301. Then, the lower electrode layer is patterned so as to form a first metal resistor 431′ and a lower electrode 431. A dielectric layer 433 is formed over the lower electrode 431.

The dielectric layer 433 is selectively etched, as described with reference to FIG. 20, to thereby form a third window 305 that exposes the fourth lower interconnection 270. Next, an upper electrode layer is formed, as described with reference to FIG. 20, to contact the fourth lower interconnection 270 through the third opening window 305. Then, the upper electrode layer is patterned so as to form a second metal resistor 435′ and an upper electrode 435. Thus, the metal resistors 435′ and 431′, which constitute a multi-layered resistor, can be formed at the same time as the upper electrode 435 and the lower electrode 431 of the MIM capacitor.

Finally, as described with reference to FIG. 22, a second insulating layer 150 is formed over the second metal resistor 435′ and the upper electrode 435. Then, as described with reference to FIG. 10, a contact 510 and an upper interconnection 590 are formed.

### Embodiment 6

In a sixth embodiment, a metal resistor is directly connected to contacts formed under metal interconnections.

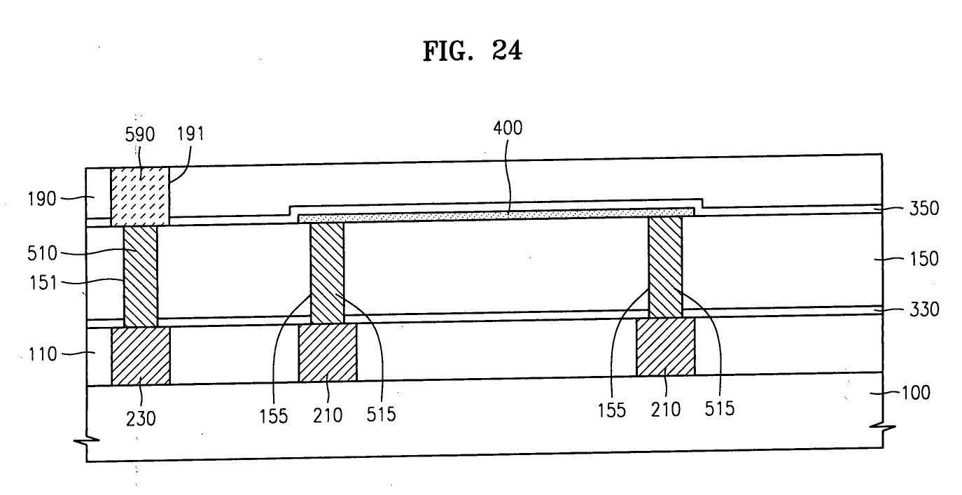

Referring to FIG. 24, as described with reference to FIG. 5, a first lower interconnection 210 and a second lower interconnection 230 are formed in a first insulating layer 110 using a damascene process. The first lower interconnection 210 is formed at a position where a metal resistor will be connected. Subsequently, a capping layer is formed on the first insulating layer 110, as described with reference to FIG. 6. In this embodiment, the capping layer functions as a first etch stop layer 330. A second insulating layer 150 is formed on the first etch stop layer 330, as described with reference to FIG. 10. Next, a first contact hole 151 and second contact holes 155, which penetrate the second insulating layer 150, are formed by an etch process using the first etch stop layer 330 as an etch stopper. The first contact hole 151 and the second contact holes 155 expose the second lower interconnection 230 and the first lower interconnections 210, respectively.

Next, a first contact 510 and second contacts 515 are formed at the same time to fill the first contact hole 151 and the second contact holes 155, respectively. The contacts 510 and 515 may be formed of a metal such as tungsten. However, if the contacts 510 and 515 are formed of copper, a capping layer (300 of FIG. 6) may be formed as described with reference to FIG. 7 and then, windows (301 of FIG. 7) are formed in the capping layer.

Subsequently, a metal resistor layer is formed on the second insulating layer 150 using any of various metallic materials, such as titanium, titanium nitride, tantalum, tantalum nitride, and tantalum silicon nitride. Next, the metal resistor layer is patterned so as to form a metal resistor 400 that is directly connected to the second contacts 515. If a capping layer (300 of FIG. 6) is adopted, the metal resistor 400 directly contacts the second contacts 515 through windows (301 of FIG. 7) as described with reference to FIG. 8.

Next, a second etch stop layer 350 is formed over the first contact 510. The second etch stop layer 350 is preferably formed of an insulating material having a sufficient etch selectivity with respect to a third insulating layer formed of silicon. nitride, which will be formed later.

Next, a third insulating layer 190 is formed on the second etch stop layer 350, as described with reference to FIG. 10. Then, a trench 191 is formed in the third insulating layer 190 as aligned with the first contact 510. Note, the etching of the third insulating layer 190 to form the trench 191 is performed using the second etch stop layer 350 as an etch stopper. The etch process is performed until the exposed portion of the second etch stop layer 350 is removed. Then, an upper interconnection 590 is formed atop the first contact 510, as described with reference to FIG. 10.

In the embodiments of the present invention, a metal resistor connected to a metal interconnection or a connection contact is formed after the metal interconnection or connection contact is formed. Thus, this method avoids eroding or removing the metal resistor during the etch process for forming a contact hole for the connection contact or a via hole. This, in turn, allows for a stable and reliable electrical connection to be established between the metal resistor and the metal interconnections. Accordingly, a very thin metal layer may be used for forming the metal resistor, e.g., a metal layer having a thickness of, for example, 30 Å to 500 or less. Therefore, the resistance of the metal resistor can be sufficiently high.

As a result, the metal resistor can be used in place of a polysilicon resistor. Thus, a metal resistor can be used in a semiconductor where a passive device occupies very large area and which requires high signal resolution. In this case, the area occupied by the passive device can be markedly reduced.

Furthermore, characteristics of the metal resistor are hardly changed after it is formed. This is because the forming of the metal resistor is not followed by the forming of the interconnections, after which high-temperature thermal processes are generally carried out in the semiconductor device manufacturing process. Consequently, the metal resistor offers a resistance corresponding to the design resistance, and analog devices having matching characteristics can be realized.

Finally, although the present invention has been particularly shown and described with reference to the preferred embodiments thereof, it will be understood by those of ordinary skill in the art that various changes in form and details may be made thereto without departing from the true spirit and scope of the present invention as defined by the following claims.

What is claimed is:

1. A semiconductor device comprising:
an insulating layer;
an interconnection including a body of copper surrounded by said insulating layer;
a capping layer that covers said insulating layer, said capping layer having a window that exposes said interconnection; and
a metal resistor that extends along said capping layer and contacts a top surface of the interconnection through said window in the capping layer.

2. The device of claim 1, wherein the metal resistor is of a material selected from the group consisting of titanium, titanium nitride, tantalum, tantalum nitride, and tantalum silicon nitride.

3. The device of claim 2, wherein the metal resistor has a thickness of about 30 Å to 1000 Å.

4. The device of claim 1, wherein the capping layer is of a material selected from the group consisting of silicon nitride and silicon carbide.

5. A semiconductor device comprising:
an electrically conductive interconnection;
an insulating layer covering said interconnection;
an electrical contact that extends through said insulating layer and is electrically connected to the interconnection; and
a metal resistor extending on said insulating layer and contacting said electrical contact.

6. A semiconductor device comprising:
an insulating layer;
an interconnection including a body of copper surrounded by said insulating layer;
an MIM capacitor disposed on said insulating layer, said MIM capacitor including a lower electrode, a dielectric, and an upper electrode;
a capping layer that covers said insulating layer, said capping layer having a window that exposes said interconnection; and
a metal resistor that extends along said capping layer and contacts a top surface of the interconnection through said window in the capping layer, said metal resistor being of the same material as one of said lower electrode and said upper electrode of the MIM capacitor.

7. The device of claim 6, wherein said capping layer extends beneath said lower electrode of the MIM capacitor.

8. The device of claim 6, wherein said lower electrode of the MIM capacitor is surrounded by said insulating layer, and said capping layer extends between said upper electrode and said lower electrode so as to serve as said dielectric of the MIM capacitor.

9. A method of manufacturing a semiconductor device, the method comprising:
forming an insulating layer on a substrate;
forming a lower interconnection of copper layer within said insulating layer;
forming a capping layer on the insulating layer to cover and protect the lower interconnection;
forming a window in the capping layer to selectively expose a top surface of the lower interconnection; and
forming, on the capping layer, a metal resistor that contacts the top surface of the lower interconnection through the window.

10. The method of claim 9, wherein the forming of the lower interconnection comprises:
forming a trench in the insulating layer,
forming a copper layer on the insulating layer to fill the trench, and
planarizing the copper layer until a top surface of the insulating layer is exposed, whereby the lower interconnection is formed in the shape of the trench.

11. The method of claim 9, wherein said forming of the capping layer comprises forming one of a silicon nitride layer and a silicon carbide layer on the insulating layer.

12. The method of claim 9, wherein said forming of the metal resistor comprises forming a layer of a material selected from the group consisting of titanium, titanium nitride, tantalum, tantalum nitride, or tantalum silicon nitride on the insulating layer.

13. A method of manufacturing a semiconductor device, the method comprising:
forming an insulating layer on a substrate;
forming a first lower interconnection and a second lower interconnection, of copper, within the insulating layer;
forming a capping layer on the insulating layer to cover and protect the first lower interconnection and the second lower interconnection;
forming a window in the capping layer to selectively expose a top surface of the first lower interconnection;
forming, on the capping layer, a metal resistor in contact with the top surface of the first lower interconnection through the window;
forming a second insulating layer over the metal resistor;
forming an electrical contact that extends through the second insulating layer and into contact with the second lower interconnection; and
forming an upper interconnection electrically connected to the electrical contact.

14. The method of claim 13, wherein said forming of the electrical or upper interconnection comprises forming a copper layer using a damascene process.

15. A method of manufacturing a semiconductor device, the method comprising:
forming an insulating layer on a substrate;
forming a first lower interconnection and a second lower interconnection of copper within the insulating layer;
forming a capping layer on the insulating layer to cover and protect the first lower interconnection and the second lower interconnection;
forming a window in the capping layer to selectively expose a top surface of the first lower interconnection;
forming, on the capping layer, a metal layer that contacts the top surface of the first lower interconnection through the window;
patterning the metal layer to form therefrom a metal electrode of a MIM capacitor and a metal resistor that contacts the first lower interconnection through the window;
forming a second insulating layer over the metal resistor and the metal electrode of the MIM capacitor; and
forming a connection contact body penetrating the second insulating layer to contact the second lower interconnection and forming an upper interconnection electrically connected to the connection contact body.

16. The method of claim 15, wherein said patterning of the metal layer forms an upper electrode of the MIM capacitor.

17. The method of claim 16, and further comprising forming a lower electrode, which is disposed under the capping layer and is opposed to the upper electrode, such that the capping layer serves as the dielectric of the MIM capacitor.

18. The method of claim 17, wherein the lower electrode is formed at the same time as the first lower interconnection and the second lower interconnection.

19. The method of claim 16, and further comprising forming a lower electrode on the capping layer and opposed to the upper electrode, and forming a dielectric layer on the lower electrode.

20. The method of claim 15, wherein said patterning of the metal layer forms a lower electrode of the MIM capacitor.

21. The method of claim 20, and further comprising forming a dielectric layer on the lower electrode, and forming an upper electrode on the dielectric layer and opposed to the lower electrode.

22. A method of manufacturing a semiconductor device, the method comprising:
forming an insulating layer on a substrate;
forming a first lower interconnection, a second lower interconnection, and a third lower interconnection of copper within the insulating layer;
forming a capping layer on the insulating layer to cover and protect the first lower interconnection, the second lower interconnection, and the third lower interconnection;
forming a first window in the capping layer to selectively expose a top surface of the first lower interconnection;
forming, on the capping layer, a lower electrode layer comprising a metal in contact with the top surface of the first lower interconnection through the first window;
patterning the lower electrode layer to form a lower electrode of an MIM capacitor, and a first metal resistor that contacts the first lower interconnection through the first window;
forming a dielectric layer over the first metal resistor and the first lower electrode;
forming a second window in the dielectric layer and the capping layer to selectively expose a top surface of the second lower interconnection;
forming, on the dielectric layer, an upper electrode layer comprising a metal that contacts the top surface of the second lower interconnection through the second window;
patterning the upper electrode layer to form an upper electrode opposed to the lower electrode, and a second metal resistor that contacts the second lower interconnection through the second window;
forming a second insulating layer over the second metal resistor and the upper electrode;
forming an electrical contact that extends through the second insulating layer into contact with the third interconnection; and
forming an upper interconnection electrically connected to the electrical contact.

23. A method of manufacturing a semiconductor device, the method comprising:
forming an interconnection;
forming an insulating layer over the interconnection;
forming an electrical contact that extends through the insulating layer and is electrically connected to the interconnection; and
forming a metal resistor on the insulating layer in contact with the electrical contact.

24. The method of claim 23, wherein said forming of the electrical contact comprises forming a layer of copper in the insulating layer.

25. The method of claim 24, and further comprising forming, on the insulating layer, a capping layer that covers and protects a surface of the copper electrical contact; and subsequently forming a window in the capping layer to expose the surface of the copper electrical contact.
